(19) United States
(12) Patent Application Publication
(10) Pub. No.: US 2011/0291152 A1
(43) Pub. Date: Dec. 1, 2011

(54) LED LEAD FRAME WITH WATER-REPELLENT LAYER

(75) Inventor: BEEN-YANG LIAW, New Taipei (TW)

(73) Assignee: HON HAI PRECISION INDUSTRY CO., LTD., New Taipei (TW)

(21) Appl. No.: 13/118,486

(22) Filed: May 30, 2011

(30) Foreign Application Priority Data
May 31, 2010 (TW) 99210241

(51) Int. Cl. H01L 33/62

(52) U.S. Cl. 257/99; 257/E33.066

(57) ABSTRACT

An LED lead frame includes a housing having a cavity for receiving an LED chip, and a pair of conductive leads mounted with the housing. Each lead includes an embedded section retained in the housing. The embedded section is plated with a silver layer thereon and a water-repellent layer disposed on the silver layer.

### BACKGROUND OF THE INVENTION

1. Field of the Invention

The present invention relates to an LED lead frame, and more particularly to an LED lead frame having a water-repellent layer between a lead and a housing so as to prevent penetration of water vapor.

2. Description of Related Art

A typical LED usually includes a lead frame with a housing of concave cavity in which a LED chip is seated. At least two conductive leads are mounted in the lead frame to be connected to the LED chip. The lead is partially embedded in the housing with one end thereof exposed in the cavity and the other end extending out of the housing for being mounted to an external device. The conductive lead is preferably plated with silver so as to obtain better light-reflection performance and better conductivity. The concave cavity is filled with transparent sealing polymer after the LED chip is securely positioned in the cavity of the housing. The sealing polymer is in solid state in nature while becomes liquid under a special high temperature.

In conventional design of an LED lead frame, a gap is likely to exist between the housing and conductive lead that embedded in housing such that external water vapor and sulfide may penetrate into the concave cavity via the gap. The water vapor accelerates the reaction of sulfide and silver and generates black substance attached on the surface of the conductive lead, thereby reducing the light-reflection performance of the lead.

Referring to FIG. 1, to overcome the above-mentioned defect, an improved lead frame is provided in which a groove 20′ is formed on the surface of the lead 2′. During the molding of the housing 1′, the resin flows into the groove 20′ and thus creates a barrier preventing the penetration of the water vapor into the cavity, thereby extending the using life of the lead frame. However, the performance of this method still fails to meet desired target.

### SUMMARY OF THE INVENTION

Accordingly, an object of the present invention is to provide an improved LED lead frame capable of more effectively preventing penetration of water vapor, and thereby extending the service life thereof.

According to one aspect of the present invention there is provided with an LED lead frame which includes a housing having a cavity for receiving an LED chip, and a pair of conductive leads mounted with the housing. Each lead includes an embedded section retained in the housing. The embedded section is plated with a silver layer thereon and a water-repellent layer disposed on the silver layer.

Other objects, advantages and novel features of the invention will become more apparent from the following detailed description when taken in conjunction with the accompanying drawings, in which:

### BRIEF DESCRIPTION OF THE DRAWINGS

FIG. 1 is a cross-sectional view of a prior art LED lead frame;

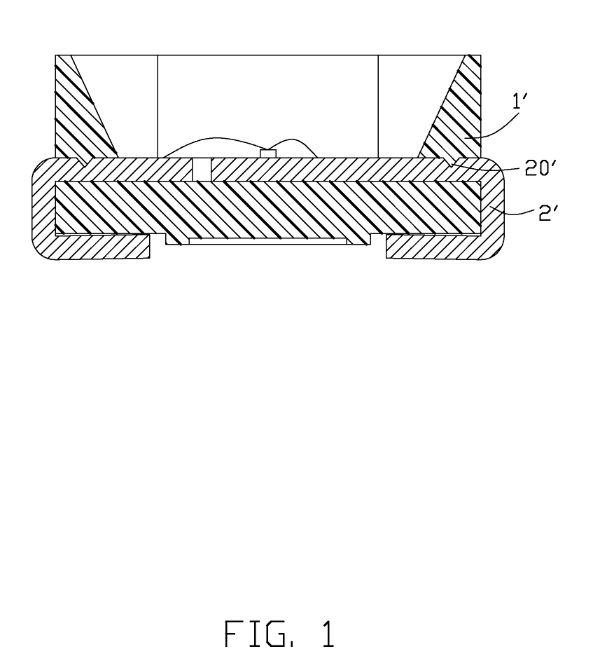

FIG. 2 is an assembled, perspective view of an LED lead frame according to a preferred embodiment of the present invention together with an LED chip received therein;

FIG. 3 is a cross-sectional view taken along the line 3-3 in FIG. 2;

FIG. 4 is a schematic view of the part inside a broken line frame labeled with “A” in FIG. 3; and

FIG. 5 is a schematic view of a part which is similar to FIG. 4 in structure according to a modified embodiment of the present invention.

### DETAILED DESCRIPTION OF THE INVENTION

Reference will now be made to the drawings to describe the present invention in detail.

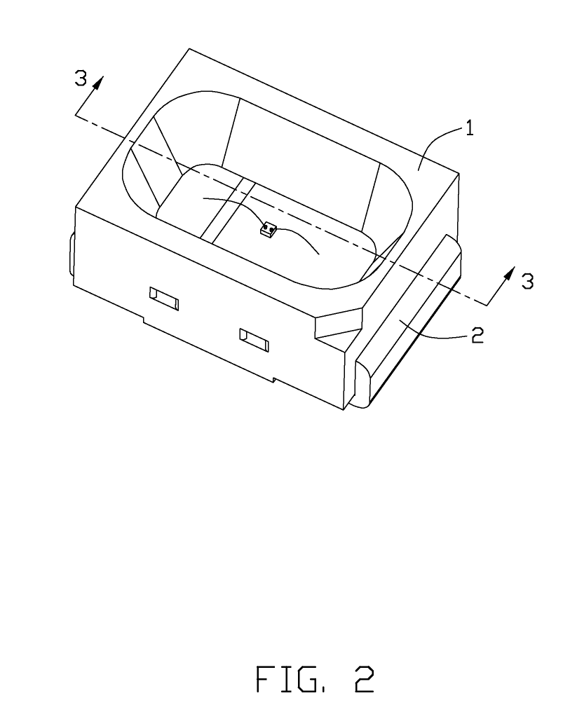

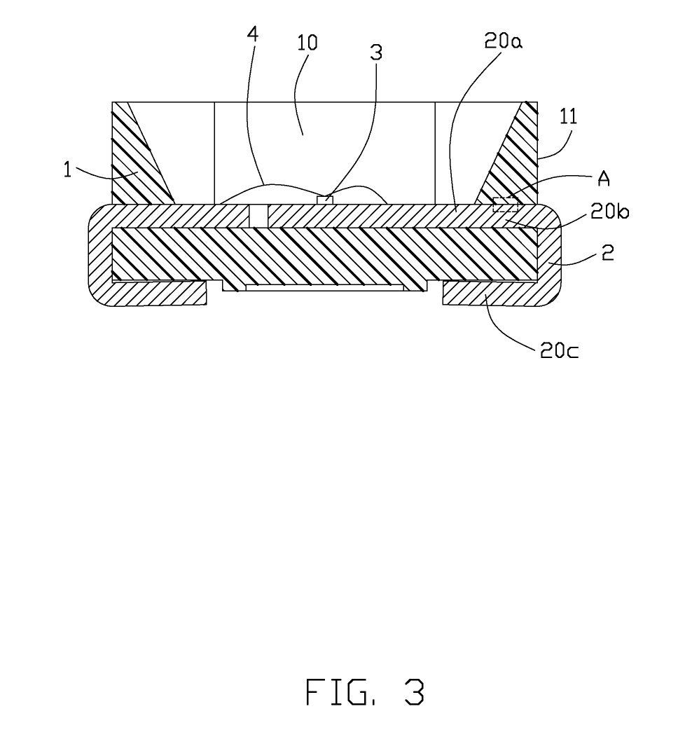

Referring to FIG. 2 and FIG. 3, a SMT-type LED lead frame is made in accordance with a preferable embodiment of the present invention. The LED lead frame is used to connect an LED chip 3 and includes a resin molded housing 1 made of resin and a pair of conductive leads 2 mounted with the housing 1.

The housing 1 has a rectangular shape, and is molded with the conductive leads 2 by injection-molding technology. The housing 1 further includes four sidewalls 11 which jointly define a cavity 10 therebetween. The cavity 10 is recessed into a top surface of the housing 1 such that a concave space is defined.

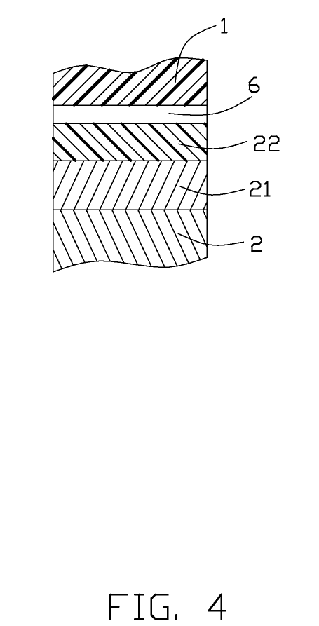

The conductive leads 2 are partially retained in the housing 1 and each has a connecting section 20a communicated with the cavity 10, an embedded section 20b physically engaged with the housing 1 and a mounting section 20c extending outside for mounting the LED lead frame to an external device (not shown). The LED chip 3 is seated upon one of the leads 2 and electrically coupled to both the leads 2 by a pair of conductive wires 4. Referring to FIG. 4, the lead 2 according to the present invention is made of copper and is plated with a silver layer 21 thereon so as to enhance light-reflection performance. A water-repellent layer 22 is further provided on the silver layer 21 to fill the gap 6 between the embedded section 20b and the housing 1 and prevent penetration of external water vapor.

According to the preferable embodiment, the water-repellent layer 22 is made of a type of water-repellent substance whose molecular formula may be: CF₃(CF₂)₄CF₂SH or CF₃(CF₂)₃CH₂CH₂SH, which both include multiple fluoro molecules in their molecule structures. Either CF₃(CF₂)₄CF₂SH or CF₃(CF₂)₃CH₂CH₂SH includes thiol compound which is likely to react and combine with the silver layer 21 on the surface of the lead 2 so as to prevent the penetration of the water vapor. The water-repellent layer 22 has a tiny thickness of 1-10 nm with a lower surface tension than the water, so the water-repellent performance is further improved.

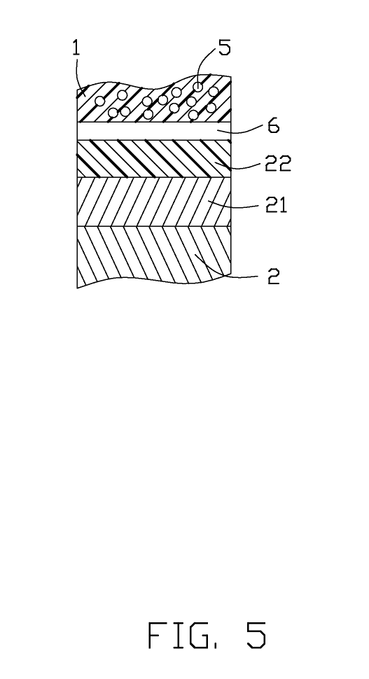

Referring to FIG. 5, a modified embodiment is further provided, in which the water-repellent layer 22 is formed and disposed on the silver layer plated on the surface of the lead 2. In addition, a substance of Teflon 5 is dispersed in the housing 1 to reduce the surface tension of the resin. The component percent of the Teflon 5 is approximately 3-10%. Because the surface tension of the improved resin is much lower than water, better water-repellent performance is obtained.

While preferred embodiments in accordance with the present invention has been shown and described, equivalent modifications and changes known to persons skilled in the art according to the spirit of the present invention are considered within the scope of the present invention as defined in the appended claims.

What is claimed is:

1. An LED lead frame, comprising:
a housing having a cavity for receiving an LED chip; and
a pair of conductive leads mounted with the housing and each comprising an embedded section retained in the housing, the embedded section being plated with a silver layer thereon and a water-repellent layer disposed on the silver layer.

2. The LED lead frame as claimed in claim 1, wherein the water-repellent layer is a composition containing a thiol compound.

3. The LED lead frame as claimed in claim 2, wherein the molecular formula of the water-repellent layer is CF₃(CF₂)₄CF₂SH.

4. The LED lead frame as claimed in claim 2, wherein the molecular formula of the water-repellent layer is CF₃(CF₂)₃CH₂CH₂SH.

5. The LED lead frame as claimed in claim 2, wherein the water-repellent layer has a lower surface tension than water.

6. The LED lead frame as claimed in claim 1, wherein the housing is made of resin with a substance of Teflon dispersed therein.

7. The LED lead frame as claimed in claim 6, wherein the percent of the substance of Teflon is approximately 3-10%.

8. The LED lead frame as claimed in claim 6, wherein the surface tension of the resin is lower than that of water.

9. An LED lead frame, comprising:
a housing having a cavity for receiving an LED chip;
a pair of conductive leads mounted with the housing and each comprising a section physically engaged with the housing; and
a water-repellent layer that has a thiol compound is provide between the section of the lead and the housing, such that the thiol compound reacts with and combines with the resin of the housing to prevent penetration of water vapor.

10. The LED lead frame as claimed in claim 9, wherein the molecular formula of the water-repellent layer is CF₃(CF₂)₄CF₂SH.

11. The LED lead frame as claimed in claim 9, wherein the molecular formula of the water-repellent layer is CF₃(CF₂)₃CH₂CH₂SH.

12. The LED lead frame as claimed in claim 9, wherein the water-repellent layer has a lower surface tension than water.

13. The LED lead frame as claimed in claim 9, wherein the section of the lead is plated with a silver layer, and said water-repellent layer is disposed on the silver layer.

14. The LED lead frame as claimed in claim 9, wherein the housing comprises a substance of Teflon dispersed therein.

15. The LED lead frame as claimed in claim 14, wherein the percent of the substance of Teflon is approximately 3-10%.

16. An LED lead frame including:
an insulative housing;
a pair of conductive leads each having a portion embedded into the housing and another portion exposed upon the housing;
the portion embedded in the housing including a precious metal layer thereon with a water repellent layer further applied upon the precious metal layer.

17. The LED lead frame as claimed in claim 16, wherein said precious metal layer is silver layer.
